(19) United States
(12) Patent Application Publication
(10) Pub. No.: US 2009/0050867 A1
(43) Pub. Date: Feb. 26, 2009

(54) FEATURE FORMED BENEATH AN EXISTING MATERIAL DURING FABRICATION OF A SEMICONDUCTOR DEVICE AND ELECTRONIC SYSTEMS COMPRISING THE SEMICONDUCTOR DEVICE

(76) Inventors: David Wells, Boise, ID (US); Chandra Mouli, Boise, ID (US)

Correspondence Address: Michael E. Romani;Micron Technology, Inc., 8000 S. Federal Way, Mail Stop 1-525, Boise, ID, 83716, US

(21) Appl. No.: 11/841,443

(22) Filed: Aug. 20, 2007

(51) Int. Cl. H01L 21/44; H01L 47/00

(52) U.S. Cl. 257/2; 438/672; 257/E47.001; 257/E21.476

(57) ABSTRACT

A method for forming a first feature within a dielectric, metal, or semiconductor material and, optionally, under an existing second feature, comprises the use of an anisotropic etch, the formation of a spacer used to prevent lateral etching, a subsequent isotropic etch to form a hollow opening, and the formation of one or more conductive and/or dielectric materials within the opening. The anisotropic etch may expose a conductive feature to which contact is to be made, depending on the particular use of the inventive method. An inventive structure is also described.

### TECHNICAL FIELD

Various embodiments of the present disclosure relate to the field of semiconductor manufacture. More particularly, the present application discloses a method for forming a feature at least partially under an existing material, for example within a semiconductor layer.

### BACKGROUND

During fabrication of semiconductor devices such as microprocessors, dynamic random access memory (DRAM), static RAM (SRAM), phase change RAM (PCRAM), logic devices, etc., various features are commonly formed. Conductive lines and other conductive features, dielectric features, diodes, transistors, source rails, contacts, and other structures, depending on the type of device, are formed as an integral part of the device.

Conductive lines, for example, may be formed in various ways. In one process to form a metal line, a blanket metal material is deposited, then masked and etched to form the conductive line. In another process known as “damascene” formation, a dielectric material is formed and masked, an opening is etched into a horizontal surface of a dielectric material, the mask is removed, a blanket metal material is formed over the horizontal surface and within the opening, and a planarization process such as chemical mechanical polishing is performed to remove the blanket metal material from over the horizontal surface which leaves metal within the opening.

After forming the conductive line or feature, a dielectric material may be formed on the conductive feature, then another conductive feature or other structure may be formed at a location above the conductive feature.

Having multiple processes available to form a desired structure is useful, as one process may be more suitable for a particular manufacturing flow than another. An additional process for forming a conductive or dielectric feature would be desirable.

### BRIEF DESCRIPTION OF THE DRAWINGS

FIGS. 1-13 are isometric depictions of intermediate in-process structures formed during fabrication of a PCRAM device using an embodiment of the present disclosure;

FIGS. 14 and 16-23 are cross sections, and FIG. 15 is a plan view, depicting various in-process structures formed during fabrication of a contact to two metal materials underlying a dielectric using an embodiment of the present disclosure;

FIG. 24 is an isometric depiction of various components which may be manufactured using devices formed with an embodiment of the present invention; and

FIG. 25 is a block diagram of an embodiment of the invention to form part of a memory device having a storage transistor array.

It should be emphasized that the drawings herein may not be to exact scale and are schematic representations. The drawings are not intended to portray the specific parameters, materials, particular uses, or the structural details of the invention, which can be determined by one of skill in the art by examination of the information herein.

### DETAILED DESCRIPTION OF THE ILLUSTRATED EMBODIMENTS

The term “wafer” is to be understood as a semiconductor-based material including silicon, silicon-on-insulator (SOI) or silicon-on-sapphire (SOS) technology, doped and undoped semiconductors, epitaxial features of silicon supported by a base semiconductor foundation, and other semiconductor structures. Furthermore, when reference is made to a “wafer” in the following description, previous process steps may have been utilized to form regions or junctions in or over the base semiconductor structure or foundation. Additionally, when reference is made to a “substrate assembly” in the following description, the substrate assembly may include a wafer with materials including dielectrics and conductors, and features such as transistors, formed thereover, depending on the particular stage of processing. In addition, the semiconductor need not be silicon-based, but may be based on silicon-germanium, silicon-on-insulator, silicon-on-sapphire, germanium, or gallium arsenide, among others. Further, in the discussion and claims herein, the term “on” used with respect to two materials, one “on” the other, means at least some contact between the materials, while “over” means the materials are in close proximity, but possibly with one or more additional intervening materials such that contact is possible but not required. Neither “on” nor “over” implies any directionality as used herein unless positively stated. The term “conformal” describes a coating material in which angles of the underlying material are preserved by the conformal material. The term “about” indicates that the value listed may be altered, as long as the alteration does not result in nonconformance of the process or structure in question to the illustrated embodiment. A “spacer” indicates a material, typically dielectric, formed as a conformal material over uneven topography then anisotropically etched to remove horizontal portions of the material and leaving vertical portions of the material. Additionally, as used herein, “conformal” or “uniform” generally refers to a ratio of horizontal surface film thickness to vertical surface film thickness during a deposition process. As a reference, a deposition process that is perfectly conformal will have about a 1:1 ratio of horizontal surface film thickness to vertical surface film thickness. That is, the film will be deposited on the horizontal surfaces at the same rate that the film is deposited on the vertical surfaces.

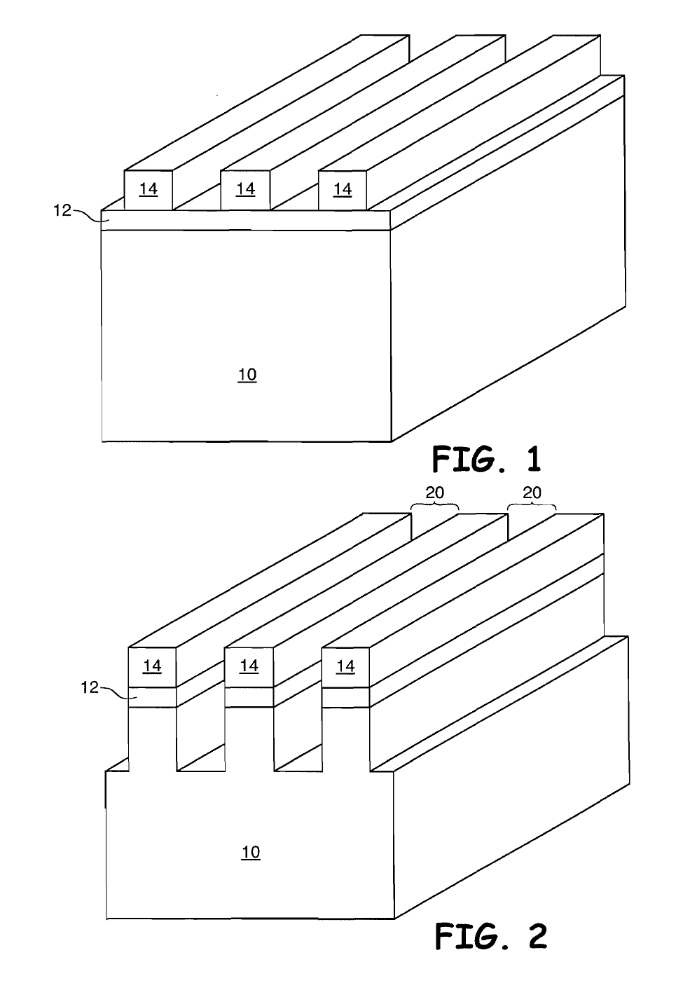

A first embodiment of a method for fabricating a semiconductor device is depicted in FIGS. 1-13. In this embodiment of the disclosure, a plurality of access devices, and more specifically diodes which provide a line of diodes and are adapted to access phase change RAM (PCRAM), are being formed. Alternatively, the invention may be used to create conductive strap or gate for planar transistors, vertical transistors, pseudo SOI or full SOI transistors, duel gate transistors, floating gate transistors or floating body memory devices. For such CMOS devices, a strap may be used to bias differential N- and P-wells to different voltages. Other devices, such as CMOS imager PIN diodes, BJT (Bipolar Junction Transistors) or power diodes may also benefit from these straps and/or gates. Depending on the application, the price for performance verses the cost/yield impact of the invention is a trade-off consideration for a given product utilizing a given process flow and design rule set. The actual PCRAM structure may comprise other features known in the art which are not immediately germane to the present invention and which are not depicted for simplicity of explanation.

As depicted in FIG. 1, a first embodiment of the present disclosure may comprise an epitaxial semiconductor material 10 formed over a semiconductor wafer (not depicted) as a part of a semiconductor wafer substrate assembly. FIG. 1 further depicts a masking material 12 such as silicon nitride (Si₃N₄) overlying the epitaxial semiconductor material 10. A patterned photoresist 14 is formed over the masking material 12. The photoresist 14 will define a line of PCRAM diode posts in a particular direction. In this embodiment, the masking material can be from between about 100 angstroms (Å) to about 1000 Å thick, while the epitaxial semiconductor material can be from between about 2000 Å to about 10,000 Å thick.

The FIG. 1 structure is anisotropically etched using photoresist 14 as a mask to etch completely through masking material 12 and at least partially into epitaxial semiconductor material 10, resulting in the structure of FIG. 2, for example, the formation of trench 20. It should be noted that for purposes of this disclosure, “anisotropically” denotes an etch which results in a vertical etch to lateral etch of about 4:1 or greater with an etch of from about 10:1 as more useful. A sufficient amount of epitaxial semiconductor material 10 is removed allowing construction of a diode structure, for example, etching of a trench of from between about 1,000 Å to about 10,000 Å extending downward and within the epitaxial semiconductor material. Any suitable anisotropic etch may be used to remove materials 10 and 12 of FIG. 1 to result in the FIG. 2 structure.

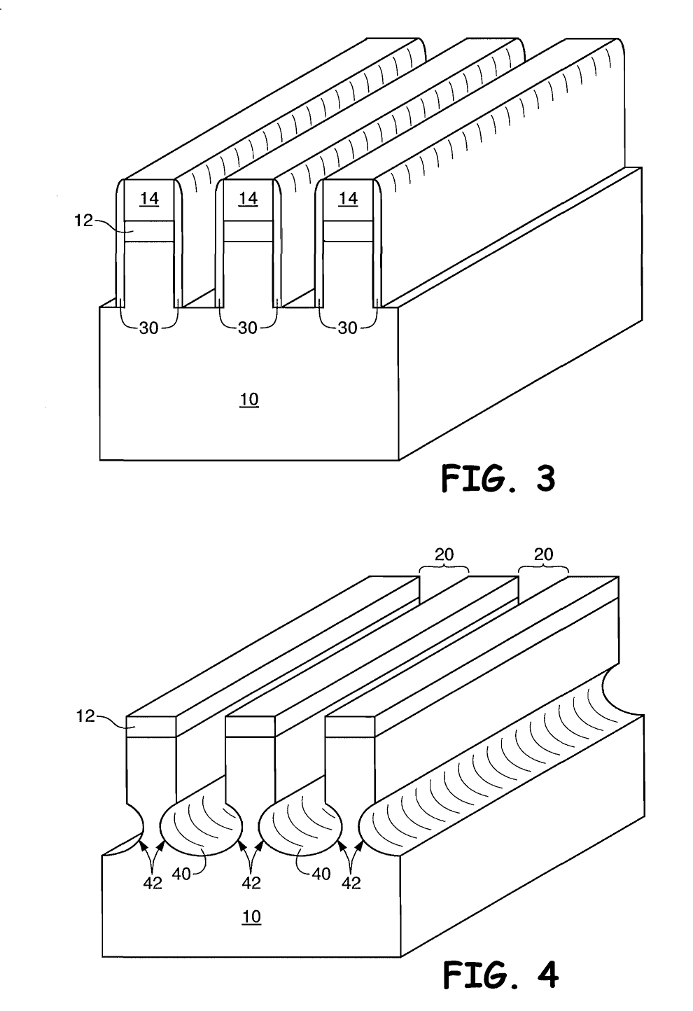

After etching the FIG. 1 structure to form openings or trenches 20 therein, a spacer material is deposited then etched to provide masking spacers 30 as depicted in FIG. 3. Spacers 30 may comprise SiO₂ or Si₃N₄ or other material that is more selective to semiconductor material 10 than to the spacer material. Materials capable of etching materials selective to SiO₂ and Si₃N₄ are known to those skilled in the art. Additionally, Spacers 30 may also comprise of one or a combination of the following organic polymers, such as carbon, hydrogen, and fluorine formed with a process using one or more of CHF₃, CH₂F₂, CH₃F, CF₄, C₂H₆, C₂H₄, NH₃, and HBr using moderate to high pressure and low bias voltage to uniformly deposit the line within the opening. A spacer material formed from SiO₂ or an organic polymer may be etched using one or more of CF₄, CHF₃, CH₂F₂, HBr, and Cl₂ at low pressure with a moderate to high bias. The bias may increase the anisotropic properties of the etch.

After forming spacers 30, the structure depicted in FIG. 3 subjected to an isotropic etch which removes epitaxial semiconductor material 10 selective to masking material 12 and spacers 30. For purposes of this disclosure, an “isotropic” etch is one which, ideally, removes exposed portions of the target material uniformly in all directions with little or no etching of other, nontargeted material. Isotropically etching the exposed epitaxial semiconductor material 10 can form, in cross section, a circular opening within the epitaxial semiconductor material 10, and is thus referred to as a “bowl etch” within this document. This etch properties and the resistance of spacers 30 and mask 12 to the etching materials, result in the hollowed out area 40 or “bowl” in the epitaxial semiconductor material 10. In a subsequent etch, photo resist 14 and spacers 30 are removed to result in the structure of FIG. 4. An isotropic etch which removes epitaxial semiconductor material 10 selective to spacer material 30 may be based on NF₃ and/or SF₆. Additionally, such isotropic etch material may also include moderating agents, for example, one or more of HBr, CHF₃ CH₂F₂, and O₂. If moderating agents are used, such agents may suppress lateral etching so the bowl 40 forms to be relatively circular in configuration rather than being elongated in lateral directions. The etching may be accomplished using either a wet or dry etch process.

While the process described above results in the FIG. 4 structure utilizing an in situ process. Additionally, an ex situ process may also be used.

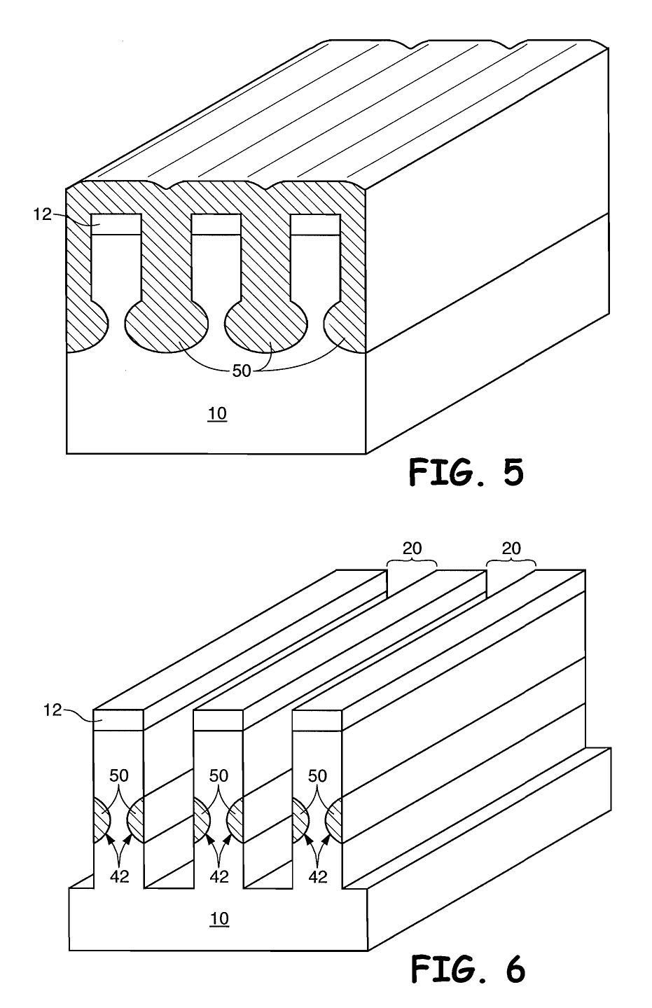

Following formation of the FIG. 4 structure, a conductive material 50, for example tungsten silicide (WSiₓ), can be deposited within trenches 20 and bowl 40, resulting in the structure of FIG. 5. Ttungsten silicide material may be deposited using a low pressure chemical vapor deposition (LPCVD) process comprising a reaction of silane (SiH₄) with tungsten hexafluoride (WF₆) at a temperature of about 400° C. and a pressure of 0.2 torr. Other deposition processes known to one skilled in the art may also be used for WSiₓ deposition.

Conductive material 50 may then be planarized, for example using mechanical planarization such as chemical mechanical planarization (CMP), and subsequently anisotropically etched to result in the FIG. 6 structure. This etch removes the conductive material 50 from trench 20, but leaves at least a portion of the conductive material 50 within the recess formed in the sidewalls 42 of the epitaxial semiconductor material 10 during the bowl etch. In addition to the present embodiment for forming PCRAM diodes, the conductive material 50 in FIG. 6 may also eventually provide a conductive gate which functions as an isolation material for the line of access devices or conductive strap, for example to lower word line resistance or to prevent neighbor disturb for the conductive strap or gate, respectively. If conductor 50 is to function as a gate, a dielectric of from about 20 Å to about 200 Å can be deposited so as to contact at least a portion of sidewalls 42 prior to conductor 50 deposition. Such dielectric material may allow for insulation of conductive material 50 from semiconductor material 10. Also, a contact (not depicted) to the conductor 50 can be provided at one end of the line to bias the gate to prevent floating. The conductive gate may be selected for its work function (WF) ability to isolate the gate from the substrate and neighboring cells. Additionally, the gate may be selected for its ability to turn on the underlying semiconductor channel according to its application. In the case of the PCRAM diode isolation, a material stable on SiO₂ dielectric, such as p+ poly or ALD TiN, could be selected for the gate. Conductive material 50 deposited within semiconductor 10 of FIG. 6 may fill less than half the opening 40 of FIG. 4 and, in one embodiment, comprises a semicircular shape.

If conductor 50 is to eventually function as a low resistivity strap through the semiconductor material 10, it can be formed directly on, and electrically coupled to, the semiconductor material 10 to provide a lower resistance electron path therethrough.

Conductor material 50 can be etched via an anisotropic etch of WSiₓ and may comprise of a plasma etch using a combination of SF₆ and N₂, or a combination of NF₃, Cl₂, and CF₄. For example, SF₆ can be utilized as an etch material and be introduced into an etch chamber at about 37 volume % along with N₂ at about 63 volume %. The chamber may be maintained a pressure of about 4 mTorr, a temperature of about 50° C., a plasma source power of about 500 W and a substrate bias power of about 80 W. The etch rate may be about 1,650 Å per minute. In addition to etching WSiₓ, this etch may increase the depth of trenches 20 by removing a portion of the epitaxial semiconductor material 10 as depicted in FIG. 6. If the WSiₓ does not remove additional epitaxial semiconductor material 10, a separate anisotropic etch may be performed which deepens the trench in epitaxial semiconductor material 10 by a desired amount.

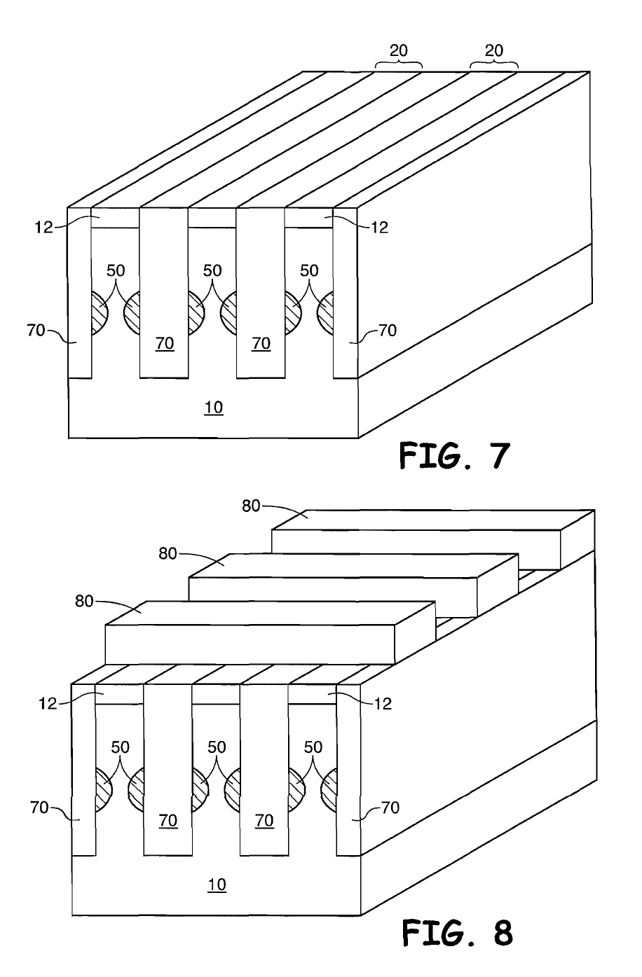

Subsequently to conductor material 50 etch, a dielectric material can be deposited within trenches 20 and over the surface of masking material 12. The dielectric material can then be planarized, for example by CMP, downwardly towards and contacting the level of masking material 12, resulting in the FIG. 7 structure comprising dielectric material 70 within trenches 20, allowing for electrical isolation of the diodes. The hard mask 12 may function as a shallow trench isolation (STI) chemical mechanical planarization (CMP) stop during subsequent processing, particularly if formed from Si₃N₄. Additionally, a spin-on dielectric (SOD) or high density plasma (HDP) oxide can be used to fill trenches 20, followed by CMP with a process selective to hard mask 12, to electrically isolate the diodes from each other.

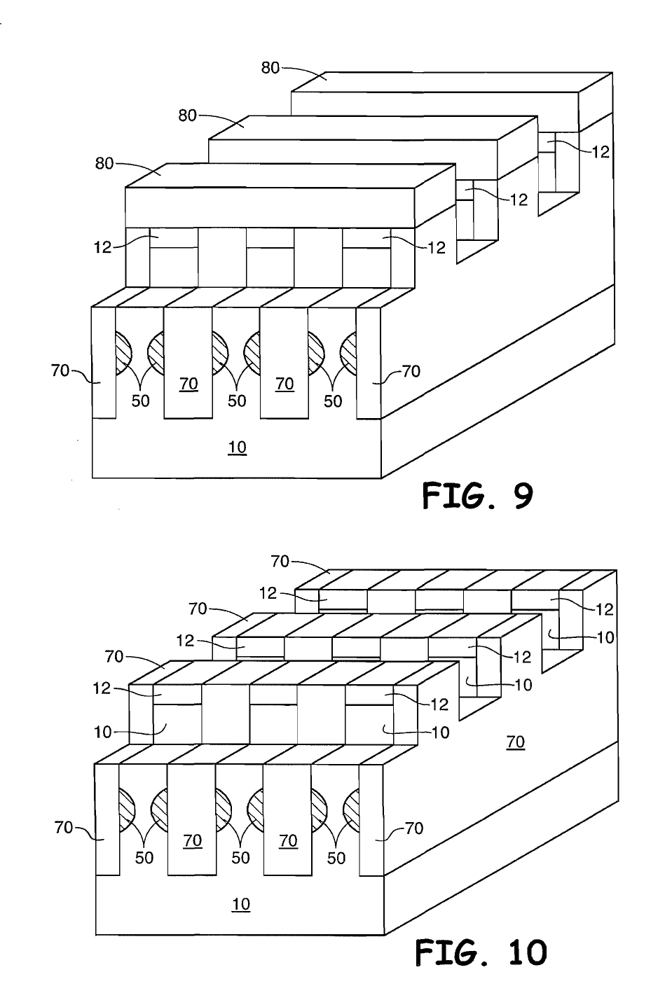

A patterned photoresist mask 80 is then formed over the FIG. 7 structure as depicted in FIG. 8. This photoresist mask 80 may define the PCRAM diode posts in a direction perpendicular to that defined by photoresist mask 14 of FIG. 2. The FIG. 8 structure is anisotropically etched to result in the FIG. 9 structure, then resist 80 is removed to result in the structure of FIG. 10.

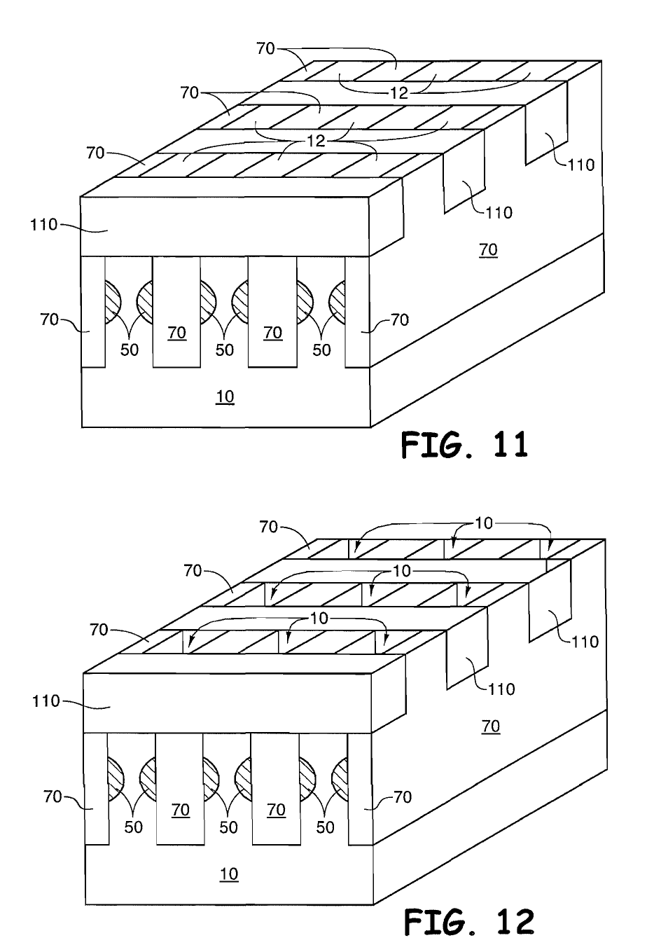

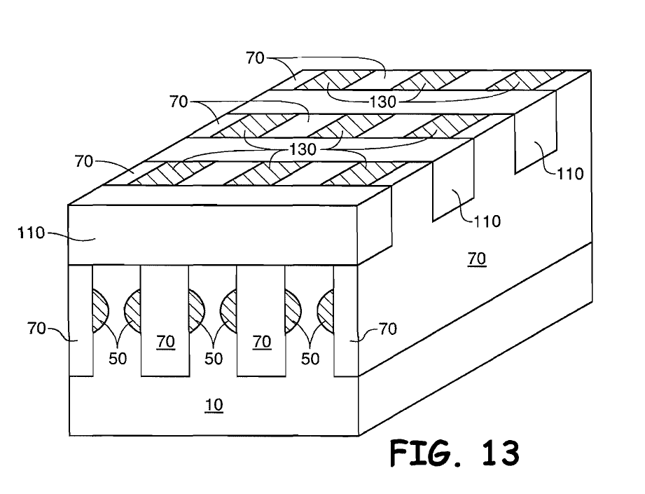

Next, a dielectric material 110 is deposited and planarized to result in the FIG. 11 structure. Masking material 12 can be etched selective to dielectric 110 to form a structure having exposed epitaxial semiconductor material 10, for example as depicted in FIG. 12. The exposed epitaxial semiconductor material 10 may be implanted, for example using a shallow p⁺ implant to create a top portion of the PCRAM diode. A self-aligned silicide (i.e. “salicide”) process may then be performed to provide silicide 130 on the exposed epitaxial semiconductor material 10 of FIG. 12 to result in the structure of FIG. 13.

Finally, wafer processing may continue according to techniques known in the art to provide other PCRAM structures integrated with the PCRAM diodes depicted and to form a completed semiconductor device.

When using a material such as WSiₓ, cobalt silicide (CoSiₓ), etc. to use feature 50 as a conducting strap, feature 50 is located beneath the top surface of the completed device of FIG. 13. If used as a strap, feature 50 will provide a low resistance path to prevent a large voltage drop along the word lines comprising bottom portion of each diode with top portion 10. Each word line is contacted on at least one end of diodes to an end of the diode line. Further, feature 50 of FIG. 6 is formed directly beneath existing masking material 12 within epitaxial semiconductor material 10, or may be formed directly beneath another existing device feature. (This instance of “beneath” refers to a line running in a direction which is perpendicular to the plane of upper surface of masking material 12 and to the surface of epitaxial semiconductor material 10 and a semiconductor wafer (not depicted) over which the depicted structures reside). Thus feature 50 provides a highly conductive physical connection between structures without requiring any additional space on the FIG. 13 structure, and results in improved scaling of crystal silicon diodes for PCRAM devices.

When using a silicide material to form a gate, the crystal silicon islands 130 located above the conductive material 50 may be used to isolate diodes in 130 from one another and reduce bipolar coupling problems inherent to adjacent diodes. A voltage can then be applied to create a depleted channel between the gates 50 on each memory node. These would all be held at an appropriate voltage such as 0V by attaching them to a voltage reference using a contact at a nondepicted location to connect the gate to ground or bias.

When using material 50 to provide a conductive strap, the “bowl etch” process may be repeated after forming straps 50 to form a high-quality dielectric material within a bowl beneath straps 50 (i.e. between straps 50 and the semiconductor wafer, not depicted). This second bowl may also be used to nearly isolate or completely isolate the straps from one another by undercutting the crystal silicon and allowing the STI fill such as SOD to SOI access structures for PCRAM.

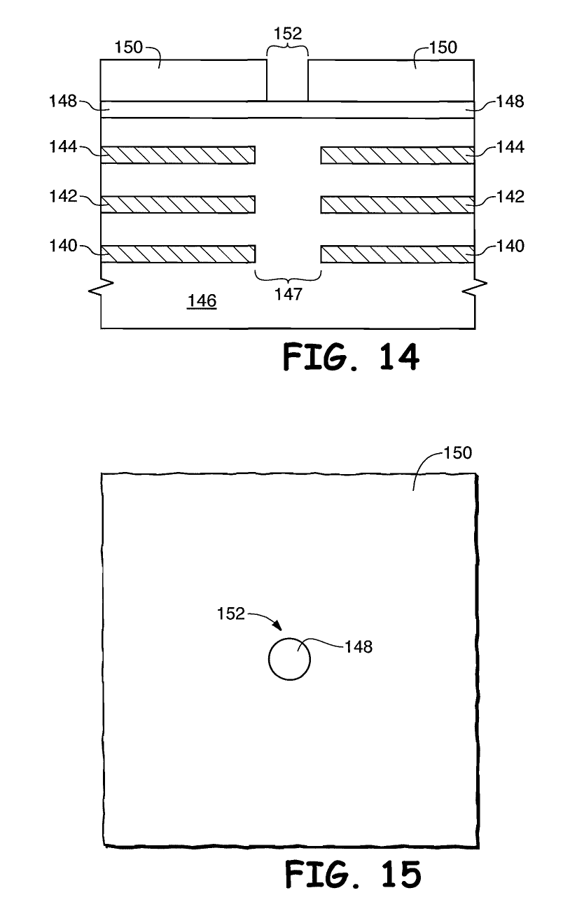

While various uses for the bowl etch in the semiconductor material is limited by device performance constraints, area, and costs (typical concerns in semiconductor manufacture) the bowl etch in the semiconductor material may be useful for PCRAM as well as other dense structure such as DRAM, flash memories and other devices. For example, another embodiment of the invention is depicted in FIGS. 14-23. In this embodiment, the inventive process is used to selectively connect two conductive materials formed within a dielectric. FIG. 14 is a cross section, and FIG. 15 is a plan view, depicting first 140, second 142, and third 144 conductive materials formed within a dielectric material 146 such as silicon dioxide (SiO₂). A space 14 separating conductive materials is also depicted. Materials 140-144 may be formed as continuous materials within one or more dielectric material then covered by a dielectric and etched through along with dielectric 146 to form circular openings, with the openings subsequently filled with the same material as dielectric 146 or with another dielectric material which has particular etch characteristics. Next, a mask material 148 which will resist an etch of dielectric 146, for example Si₃N₄, is formed over dielectric 146. In this embodiment, each conductive material has a circular opening therethrough, and additional conductive materials (not depicted) exist under conductive material 140; further, a contact can be formed which electrically couples first 140 and third 144 conductive materials, with no contact being made with second conductive material 142. A patterned photoresist material 150 having an opening 152 therein is formed on mask material 148.

With continuing reference to FIG. 14, opening 152 in photoresist material 150 may be vertically aligned with space 147 between the conductive materials 140-144 and may also have a similar diameter to that of opening 152. However, opening 152 location may vary depending on process variances, mask tolerances, physical dimensions, and specific materials used. The opening 152 in the dielectric material may be slightly larger or slightly smaller than space 147. The tolerance of the bowl size and material spacing is governed by the alignment variation of opening 152.

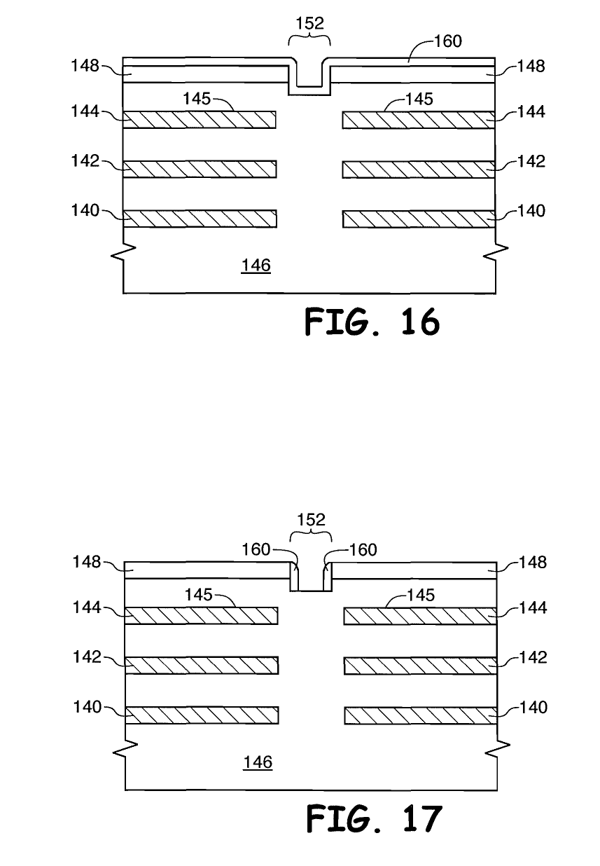

After forming the structure of FIGS. 14 and 15, masking material 148 is etched at opening 152 selective to photoresist material 150 extending opening 152 through mask material 148 and at least partially into dielectric material 146. Opening 152 can be etched to a depth above an upper surface 145 of the third conductor 144. A conformal spacer material 160 can be deposited over masking material 148 and within the opening 152 to result in the FIG. 16 structure. The spacer material 160 can be a material which may be etched selective to dielectric 146, and may be the same material as masking material 148. For example, a SiO₂ dielectric 146 and a Si₃N₄ masking material 148, spacer material 160 may also comprise Si₃N₄. The thickness for spacer material 160 may be less than half the width of opening 152 and is formed conformally.

Subsequently, conformal spacer material 160 is etched by processes known in the art to form conductive spacers on sidewalls of masking material 148 and dielectric 146 as depicted in FIG. 17. The spacer etch process may also remove a portion of masking material 148, particularly if the same material is used for both masking material 148 and spacer material 160. Thus in one embodiment, masking material 148 may be formed to a sufficient thickness to prevent complete removal during this and a subsequent spacer etch described below.

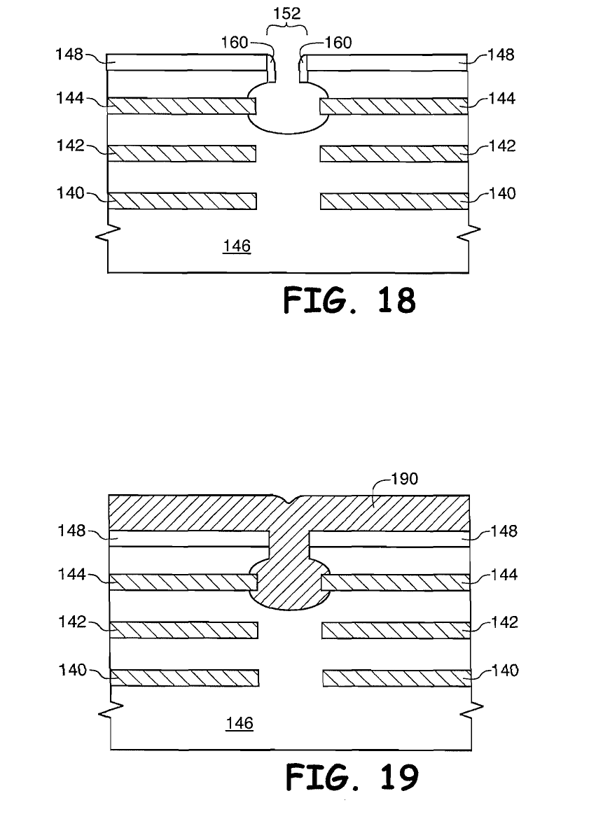

Next, an isotropic bowl etch of dielectric 146 may be performed selective to spacers 160, masking material 148, and third conductive material 144, exposing third conductive material 144 as depicted in FIG. 18. Suitable wet and dry isotropic etches are known in the art.

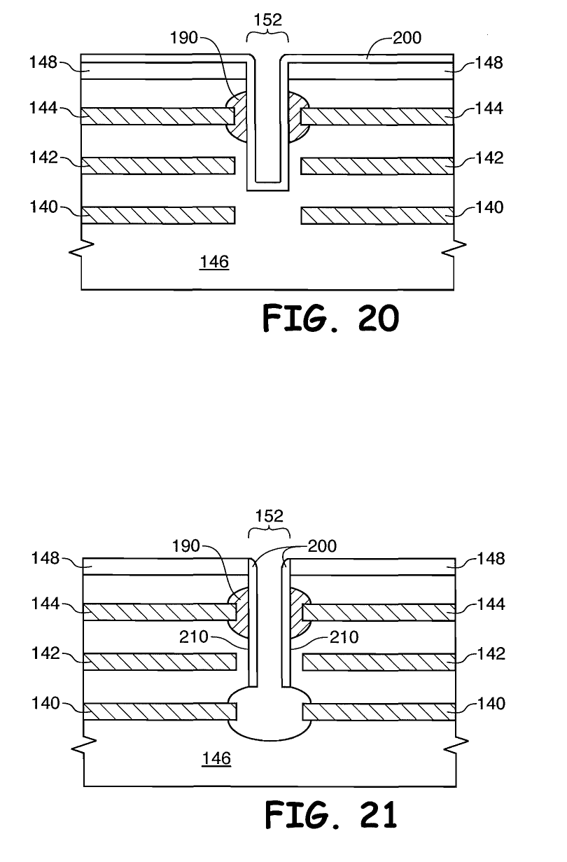

After exposing third conductive material 144, a conductive material 190 is formed within the etched opening as depicted in FIG. 19 to contact the third conductive material 144 and to be electrically coupled therewith. Suitable materials may comprise titanium nitride formed using atomic layer deposition (ALD), ALD tantalum nitride, and furnace CVD titanium nitride. Furnace titanium nitride is conventionally used as a diffusion barrier during semiconductor manufacture. Material 190 may be planarized, for example by CMP, resulting in removal from the surface of mask material 148, followed by an anisotropic etch to remove a majority of material 190 from the opening 152 in the dielectric, for example as depicted in FIG. 20. Depending on the etch chemistry chosen, a portion of dielectric 146 may be anisotropically etched to deepen the opening below the level of the second conductive material 142 as depicted, or separate etches may be used to remove the conductive material 190 and to deepen the opening in the dielectric 146.

Next, a conformal spacer material 200, for example Si₃N₄, can be deposited to within opening 152 as depicted in FIG. 20. Conformal spacer material 200 may be deposited to a thickness of less than half the width of the opening 152, for example to about 60 Å. A spacer etch is then performed providing spacers on sidewalls 210. The spacer etch of material 200 removes material 200 from the upper surface of material 148 and may partially etch material 148, particularly if masking material 148 and spacer material 200 are formed from the same material.

Following the etching of material 200 to form spacers, an anisotropic etch is performed to remove dielectric 146 selective to spacers 200, conductive material 190, masking material 148, and first conductive material 140. This etch may expose the first conductive material 140 to result in a structure similar to that depicted in FIG. 21. Next, spacers 200 are removed.

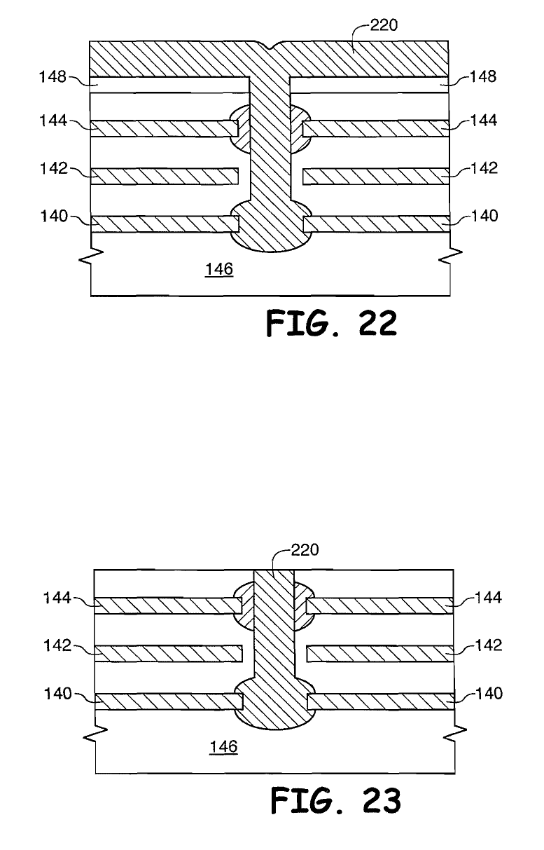

A conductive material 220 is deposited subsequently within the etched opening 152 and over mask material 148 as depicted in FIG. 22 to electrically couple third conductive material 144 and first conductive material 140. In one embodiment, second conductive material 142 has been bypassed and therefore not electrically coupled with first 144 and third 146 conductive materials. Of course, any combination of electrical coupling between conductive materials 140-144 is possible. For example, conductive materials 140-144 may all be electrically coupled together.

The FIG. 22 structure may then be planarized, for example using CMP, to remove conductive material 220 and masking material 148 to result in the FIG. 23 structure. A conductive line or other conductive feature may then be formed to contact conductive material 220 to provide electrical access to first 142 and third 146 conductive materials. Processing may then continue to form a completed structure.

In an alternate embodiment, material 190 may be omitted in the previous process. Spacer material 200 of FIG. 20 would form conformally within the bowl region of FIG. 18, the spacer etch and bowl etch similar to that which occurs between FIGS. 20 and 21 would be performed, spacer material 200 would be removed, and material 220 would be formed. Material 220, rather than electrically coupling with material 144 through material 190 would physically contact both of materials 144 and 140. This may provide a higher quality contact to material 144 as there would be no fissure formed as may be found between materials 190 and 220 of FIG. 23, for example.

In another embodiment, an opening need not be formed through a horizontal material such that only one edge of the conductive material is contacted with material 190 and/or material 220. With regard to FIG. 23, for example, only portions of materials 140, 142, and 144 which are to the left of material 220 need be present to provide electrical contact between materials 140 and 144.

In addition to connecting conduction lines and gates, a process similar to that described in the previous depicted embodiment may be used to couple a capacitor built in a planar multistack pattern similar to the conductor stack of FIGS. 14-23. In a capacitor configuration, the alternate conductor materials would be coupled with a regional voltage or ground connection and the alternating conduction materials attached to the conductive plug in FIG. 23 would be attached to a line or transistor as a capacitor. This may be used as a DRAM storage capacitor, a ballast capacitor for CMOS imagers, antifuse structures, a replacement for other capacitors found in integrated circuits, or for battery electrodes.

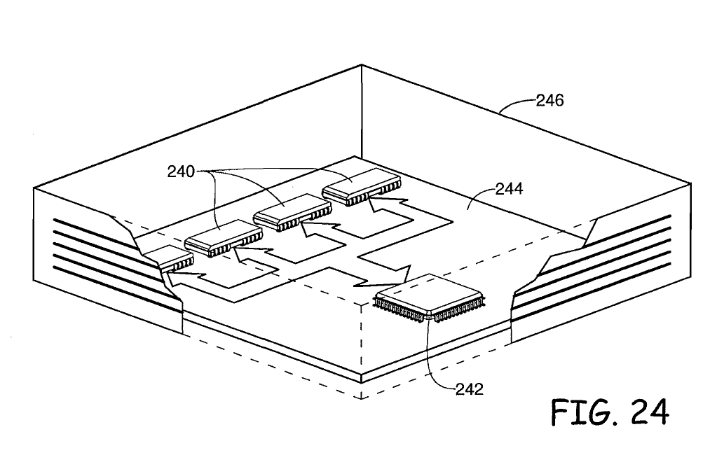

As depicted in FIG. 24, a semiconductor device 240 formed in accordance with an embodiment of the disclosed invention may be attached along with other devices such as a microprocessor 242 to a printed circuit board 244, for example to a computer motherboard or as a part of a memory module used in a personal computer, a minicomputer, or a mainframe 246. FIG. 24 may also represent use of device 240 in other electronic devices comprising a housing 246, for example devices comprising a microprocessor 242, related to telecommunications, the automobile industry, semiconductor test and manufacturing equipment, consumer electronics, or virtually any piece of consumer or industrial electronic equipment.

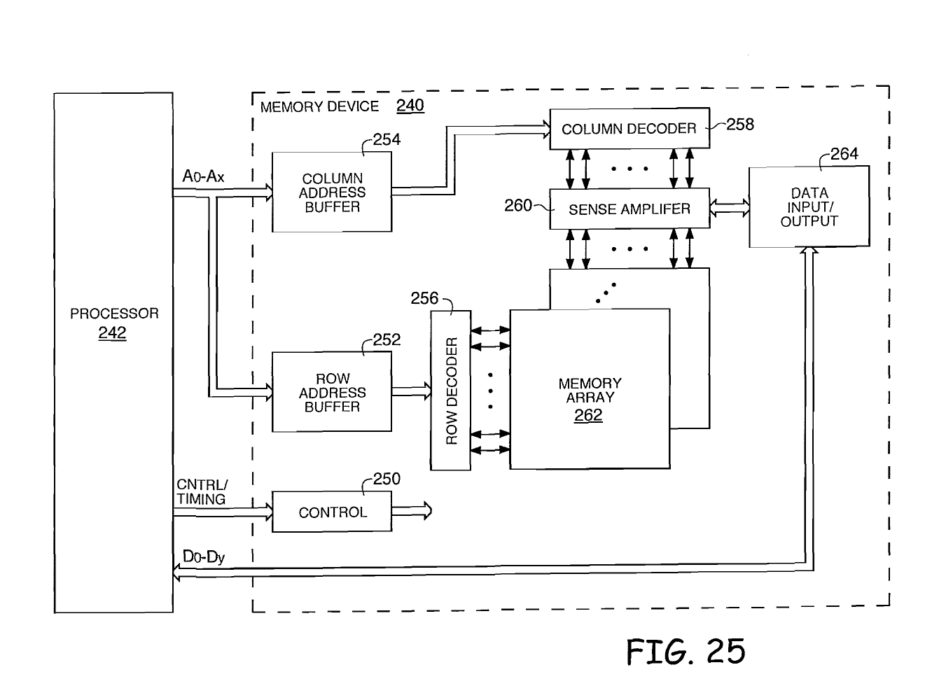

The process and structure described herein can be used to manufacture a number of different structures comprising a feature formed according to the inventive process. FIG. 25, for example, is a simplified block diagram of a memory device such as a DRAM having features which may be formed using an embodiment of the present invention. The general operation of such a device is known to one skilled in the art. FIG. 25 depicts a processor 242 coupled to a memory device 240, and further depicts the following basic sections of a memory integrated circuit: control circuitry 250; row address buffer 252 and column address buffer 254; row decoder 256 and column decoder 258 decoders; sense amplifiers 260; memory array 262; and data input/output 264.

While this disclosure has been described with reference to illustrative embodiments, this description is not meant to be construed in a limiting sense. Various modifications of the illustrative embodiments, as well as additional embodiments of the invention, will be apparent to persons skilled in the art upon reference to this description. It is therefore contemplated that the appended claims will cover any such modifications or embodiments as fall within the true scope of the disclosure.

1. A method used during semiconductor device fabrication to provide first and second conductive features, comprising:
forming a material to be etched;
etching an opening within the material to be etched, wherein the opening comprises a first portion having vertically oriented cross sectional sidewalls and a second portion having spherical cross sectional sidewalls;
forming a conductive material which substantially fills the spherical opening; and
etching the conductive material through the first portion of the opening to separate the conductive material into first and second conductive features which are electrically isolated from each other.

2. The method of claim 1 further comprising:
forming a device feature on an upper surface of the material to be etched; and
etching the material to be etched such that a portion of the second opening is located directly beneath the device feature.

3. The method of claim 2 further comprising forming the device feature prior to the etching of the material to be etched.

4. The method of claim 2 further comprising forming the conductive material within the second portion of the opening such that a portion of the conductive material is located directly beneath the device feature subsequent to the etching of the conductive material to separate the conductive material into the first and second conductive features.

5. A method comprising:
providing a material to be etched having first and second sidewalls which define a first portion of a first trench therein; forming a first protective spacer on the first sidewall and a second protective spacer on the second sidewall;
isotropically etching the material to be etched through the first portion of the first trench using the first and second spacers as a lateral etch mask to form a second portion of the first trench;
forming a conductive material within at least the second portion of the first trench; and
anisotropically etching the conductive material within the second portion of the first trench through the first portion of the first trench, and further etching the material to be etched through the first portion of the first trench to form a third portion of the first trench wherein, subsequent to anisotropically etching the conductive material, a portion of the conductive material remains in the second portion of the first trench.

6. The method of claim 5 wherein the conductive material is a first conductive material and the method further comprises:
forming a first dielectric material within the first and third portions of the first trench;
forming a mask material portion in a direction substantially perpendicular with a direction of the first trench;
etching the first dielectric material and the material to be etched using the mask material portion as a pattern to form a second trench in the first dielectric material and the material to be etched, wherein the second trench is in a direction substantially perpendicular with the direction of the first trench;
removing the mask material;
forming a second dielectric material within the second trench; and
forming a second conductive material to contact both the first dielectric material and the second dielectric material.

7. The method of claim 6 further comprising etching at least a semiconductor material to provide the material to be etched, wherein the first and second conductive materials and the semiconductor material provide at least a portion of a diode.

8. The method of claim 7 wherein the mask material portion is a first mask material portion and the method further comprises:
providing a second mask material portion in a direction parallel with a first direction;
etching the material to be etched using the second mask material portion to form the first and second sidewalls from the material to be etched;
forming the first and second spacers on the first and second sidewalls;
removing the second mask to expose the semiconductor material; and
forming a self-aligned silicide material from the exposed semiconductor material to provide the second conductive material.

9. A semiconductor device, comprising:
a semiconductor material;
a plurality of diodes at least partially within the semiconductor material, wherein the plurality of diodes provide a line of diodes and each diode comprises a contact;
an opening within the semiconductor material; and
a conductive strap filling less than half of the opening within the semiconductor material, wherein the conductive strap is electrically coupled with the contact of each diode of the plurality of diodes which provide the line of diodes.

10. The semiconductor device of claim 9 wherein the conductive strap comprises a semicircular shape.

11. The semiconductor device of claim 10 wherein the conductive strap is a first conductive strap and the semiconductor device further comprises a second conductive strap comprising a semicircular shape which fills less than half the circular portion of the opening within the semiconductor material.

12. The semiconductor device of claim 9 further comprising phase change random access memory (PCRAM) elements, wherein the plurality of diodes are adapted to access the PCRAM elements.

13. The semiconductor device of claim 9 wherein the opening is circular in structure.

14. A semiconductor device, comprising:
a semiconductor material;
a plurality of diodes at least partially within the semiconductor material, wherein the plurality of diodes provide a line of diodes;
an opening having a circular portion within the semiconductor material; and
a conductive gate filling less than half the circular portion of the opening within the semiconductor material, wherein the conductive gate isolates the line of diodes from adjacent conductive structures.

15. The semiconductor device of claim 14 wherein the line of diodes is a first line of diodes and the adjacent conductive structures is a second line of diodes.

16. The semiconductor device of claim 14 wherein the conductive gate comprises a semicircular shape.

17. The semiconductor device of claim 16 wherein the conductive gate is a first conductive gate and the semiconductor device further comprises a second conductive gate comprising a semicircular shape which fills less than half the circular portion of the opening within the semiconductor material.

18. The semiconductor device of claim 14 further comprising phase change random access memory (PCRAM) elements, wherein the plurality of diodes are adapted to access the PCRAM elements.

19. A semiconductor device, comprising:
a semiconductor material;
a plurality of diodes at least partially within the semiconductor material, wherein the plurality of diodes provide a line of access devices and each access device comprises a contact;
an opening having a circular portion within the semiconductor material; and
a conductive strap filling less than half the circular portion of the opening within the semiconductor material, wherein the conductive strap is electrically coupled with the contact of each access device of the plurality of access devices which provide the line of access devices.

20. The semiconductor device of claim 19 wherein the conductive strap comprises a semicircular shape.

21. The semiconductor device of claim 20 wherein the conductive strap is a first conductive strap and the semiconductor device further comprises a second conductive strap comprising a semicircular shape which fills less than half the circular portion of the opening within the semiconductor material.

22. The semiconductor device of claim 21 further comprising phase change random access memory (PCRAM) elements, wherein the plurality of access devices are adapted to access the PCRAM elements.

23. A semiconductor device, comprising:
a semiconductor material;
a plurality of access devices at least partially within the semiconductor material, wherein the plurality of access devices provide a line of access devices;
an opening having a circular portion within the semiconductor material; and
a conductive gate filling less than half the circular portion of the opening within the semiconductor material, wherein the conductive gate isolates the line of access devices from adjacent conductive structures.

24. The semiconductor device of claim 23 wherein the line of access devices is a first line of access devices and the adjacent conductive structures is a second line of access devices.

25. The semiconductor device of claim 23 wherein the conductive gate comprises a semicircular shape.

26. The semiconductor device of claim 25 wherein the conductive gate is a first conductive gate and the semiconductor device further comprises a second conductive gate comprising a semicircular shape which fills less than half the circular portion of the opening within the semiconductor material.

27. The semiconductor device of claim 23 further comprising phase change random access memory (PCRAM) elements, wherein the plurality of access devices are adapted to access the PCRAM elements.

28. A method, comprising:
forming at least a first conductive feature comprising a surface and a second conductive feature comprising a surface encased within a dielectric;
anisotropically etching the dielectric to form a first portion of an opening therein having a lowest extent;
isotropically etching the dielectric at the lowest extent of the first portion of the opening through the first portion of the opening to form a second portion of the opening having a lowest extent within the dielectric and to expose the first conductive feature surface;
forming a first conductive material within the first and second portions of the opening to contact the first conductive feature surface;
anisotropically etching the first conductive material through the first portion of the opening to leave a portion of the third conductive material within the second portion of the opening;
etching the dielectric at the lowest extent of the second portion of the opening to form a third portion of the opening having a lowest extent;
isotropically etching the dielectric at the lowest extent of the third portion of the opening through the first, second, and third portions of the opening to form a fourth portion of the opening within the dielectric and to expose the second conductive feature surface; and
forming a second conductive material within at least the second, third, and fourth portions of the opening to electrically couple the first conductive material and the second conductive material.

29. The method of claim 28 wherein the anisotropic etching of the dielectric to form the first portion of the opening therein results in the formation of the lowest extent of the first portion of the opening at a level above the first conductive feature surface.

30. The method of claim 28 wherein the isotropic etching of the dielectric to form the second portion of the opening results in the formation of the lowest extent of the second portion of the opening at a level below the first conductive feature surface and above the second conductive feature surface.

31. The method of claim 28 wherein the etching of the dielectric to form the third portion of the opening results in the formation of the lowest extent of the third opening at a level below the first conductive feature and above the second conductive feature.

32. The method of claim 28 wherein isotropic etching of the dielectric to form the fourth portion of the opening results in the formation of a lowest extent of the fourth portion of the opening which is at a level below the second conductive feature.

33. The method of claim 28 further comprising:
etching through the first conductive feature to form a void therein;
forming the dielectric material within the void; and
anisotropically etching the dielectric material within the void to form at least a portion of the opening therein.

34. The method of claim 28 further comprising:
forming at least a third conductive feature comprising a surface, wherein the third conductive feature is interposed directly between the first conductive feature and the second conductive feature and, subsequent to forming the second conductive material, the third conductive feature is electrically isolated from the first and second conductive features.

35. The method of claim 34 further comprising:
anisotropically etching through the first conductive feature and the third conductive feature to form a void therein;
forming the dielectric material within the void; and
anisotropically etching the dielectric material within the void to form at least a portion of the opening therein.

36. The method of claim 35 further comprising leaving the second conductive feature unetched during the etching of the first conductive feature and the third conductive feature.

37. A semiconductor device, comprising:
a dielectric material,
a plurality of gated semiconductor devices within the dielectric material, wherein the plurality of gated semiconductor devices provides for a line of gated semiconductor devices;
an opening within the dielectric material; and
a conductive material filling less than half of the opening within the dielectric material, wherein the conductive material acts as conductive strap to lower resistance drop about a device body.
